(19) United States
(12) Patent Application Publication
(10) Pub. No.: US 2013/0083953 A1
(43) Pub. Date: Apr. 4, 2013

(54) MOBILE ELECTRONIC DEVICE PROTECTIVE COVER WITH TABLET PC AND FLAT SPEAKER SUPPORT FUNCTION

(71) Applicant: Yun Yu Chang, New Taipei City (TW)

(72) Inventor: Yun Yu Chang, New Taipei City (TW)

(21) Appl. No.: 13/249,211

(22) Filed: Sep. 29, 2011

(51) Int. Cl. H04R 1/02; H05K 5/03

(52) U.S. Cl. 381/333; 361/679.01

(57) ABSTRACT

A mobile electronic device protective cover consists of hinged front panel and rear panel. The rear panel includes a holder portion adapted for holding a mobile electronic device, for example, tablet PC, two pop-up type flat speaker sleeves receivably fastened to the holder portion at two opposite lateral sides for holding one respective speaker driver, a connection portion bonded to the back wall of the holder portion, a box accommodating therein an acoustic transducer module, a subwoofer and a rechargeable power source, a support portion adapted for supporting the holder portion on the front panel in a standing position, and a folding line connected between the connection portion and the support portion.

### BACKGROUND OF THE INVENTION

1. Field of the Invention

The present invention relates to tablet PC protective technology and more particularly, to a mobile electronic device protective cover that can be arranged into the form of a stand to support a tablet PC and a pair of flat speaker drivers in a standing position for high-quality audio output.

2. Description of the Related Art

Commercial digital data processing devices, such as tablet PC, are technique oriented designs. When compared to regular portable computers, these devices are relatively lighter, thinner, shorter and smaller. Due to limited internal space, a tablet PC does not equipped with a Hi-Fi audio system. The speaker system of a tablet PC cannot provide a high quality audio output. When using a tablet PC to watch movies or to listen to music, people may use a support device to support the tablet PC in a tilted or vertical position and connect a set of external Hi-Fi speakers to the audio output port of the tablet PC. However, it is inconvenient to carry a tablet PC with the related support device and the attached Hi-Fi speakers.

Therefore, it is desirable to provide a mobile electronic device protective cover that can be arranged into a standing form to support the tablet PC and a pair of flat speakers in a tilted or quasi-vertical position.

### SUMMARY OF THE INVENTION

The present invention has been accomplished under the circumstances in view. It is the main object of the present invention to provide a mobile electronic device protective cover, which can be conveniently arranged into a stand to support a mobile electronic device and a pair of flat speaker drivers in a standing position for providing a Hi-Fi sound quality, strong bass and full-range stereo performance. It is another object of the present invention to provide a mobile electronic device protective cover, which can be conveniently arranged into a stand to support a tablet computer and a pair of flat speaker drivers in a standing position for providing a Hi-Fi sound quality, strong bass and full-range stereo performance. It is still another object of the present invention to provide a mobile electronic device protective cover, which has light and thin characteristics and is convenient for carrying a tablet computer and a subwoofer or pair of flat speaker drivers.

To achieve these and other objects of the present invention, a mobile electronic device protective cover comprises a front panel and a rear panel hinged together. The rear panel comprises a holder portion adapted for holding a mobile electronic device, for example, a tablet computer, a connection portion bonded to a part of the back wall of the holder portion, a support portion adapted for supporting the holder portion on the front panel in a standing position, and a folding line connected between the connection portion and the support portion.

Further, the rear panel further comprises at least one, for example, two pop-up type flat speaker sleeves fastened to the holder portion and movable relative to the holder portion between a received position kept inside the holder portion and an extended position disposed outside the holder portion for holding one respective speaker driver. The holder portion defines therein a passageway extending through opposing left and right sides thereof and an opening at each of two distal ends of the passageway. The pop-up type flat speaker sleeves are accommodated in the passageway, each having a strap fixedly fastened to one side thereof. The strap has a free end inserted through one opening at one end of the passageway and fixedly fastened to the inside of the passageway.

Further, the rear panel has a box attached thereto for accommodating therein an acoustic transducer module, a subwoofer and a rechargeable power source. Further, the box has a plurality of sound penetration holes corresponding to the subwoofer. The subwoofer is electrically connected to the acoustic transducer module. The acoustic transducer module is electrically connectable to a tablet PC held in the holder portion for converting outputted audio signals of the tablet PC into sound for output by the subwoofer.

Thus, a user can conveniently set the mobile electronic into the form of a stand to hold a tablet PC in a standing position convenient for reading. As the mobile electronic device protective cover is practical for holding a tablet computer in a standing position and has an acoustic transducer module and a subwoofer accommodated in the attached box, it enables the tablet computer to achieve a high-power, high-quality audio performance, bringing to the user a stunning audio and visual extravaganza.

### BRIEF DESCRIPTION OF THE DRAWINGS

FIG. 1 is an exploded view of a mobile electronic device protective cover in accordance with the present invention.

FIG. 2 is a plain view of the mobile electronic device protective cover in accordance with the present invention.

FIG. 3 is a perspective rear side view illustrating a status of use of the mobile electronic device protective cover in accordance with the present invention.

FIG. 4 is a perspective front view illustrating a status of use of the mobile electronic device protective cover in accordance with the present invention.

FIG. 5 corresponds to FIG. 4, illustrating the pop-up type flat speaker sleeves with the respective flat speaker drivers disposed at two opposite lateral sides relative to the holder portion.

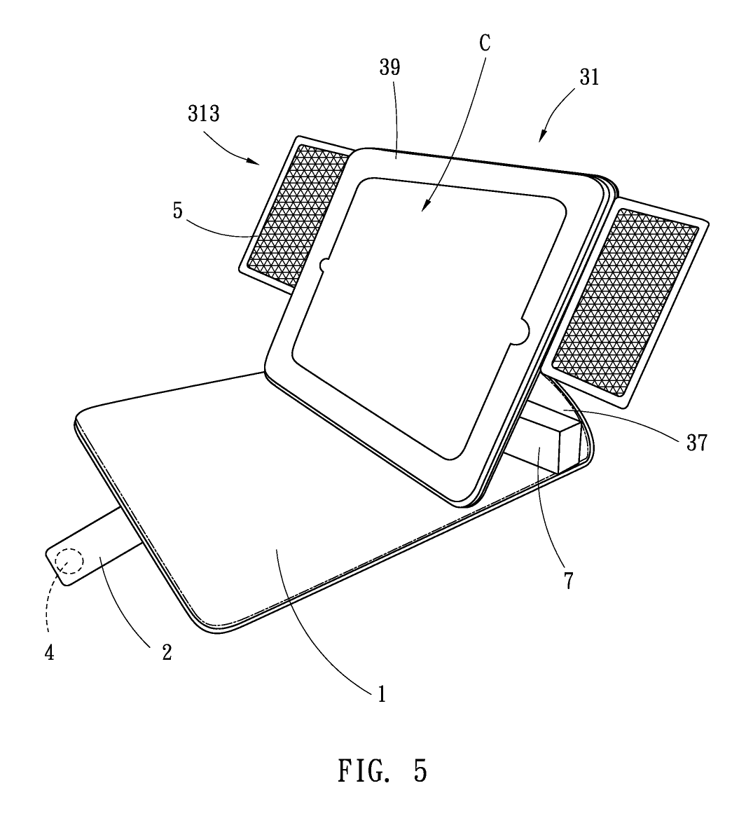

FIG. 6 is a schematic drawing of a part of the present invention, illustrating insertion of a tablet PC into the frame of the holder portion.

FIG. 7 is a sectional view of the present invention, illustrating a tablet PC received in the frame of the holder portion of the rear panel.

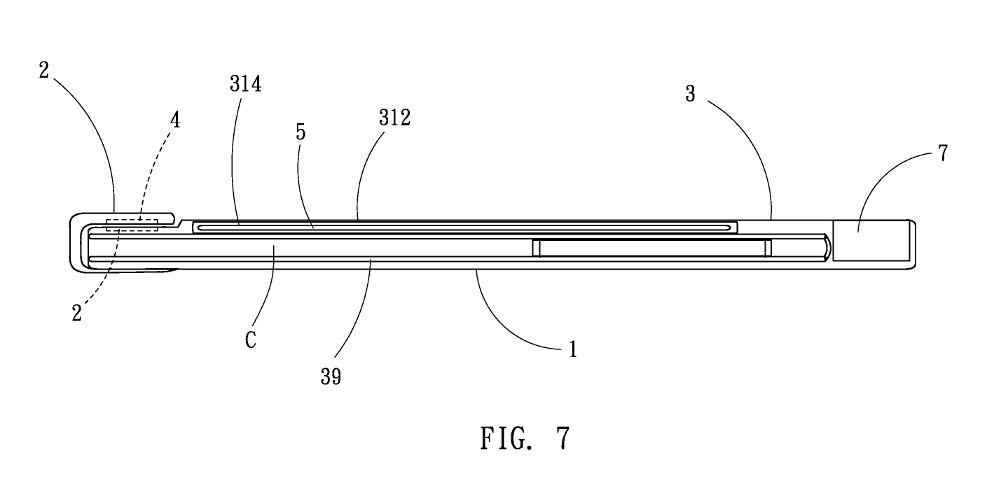

### DETAILED DESCRIPTION OF THE PREFERRED EMBODIMENT

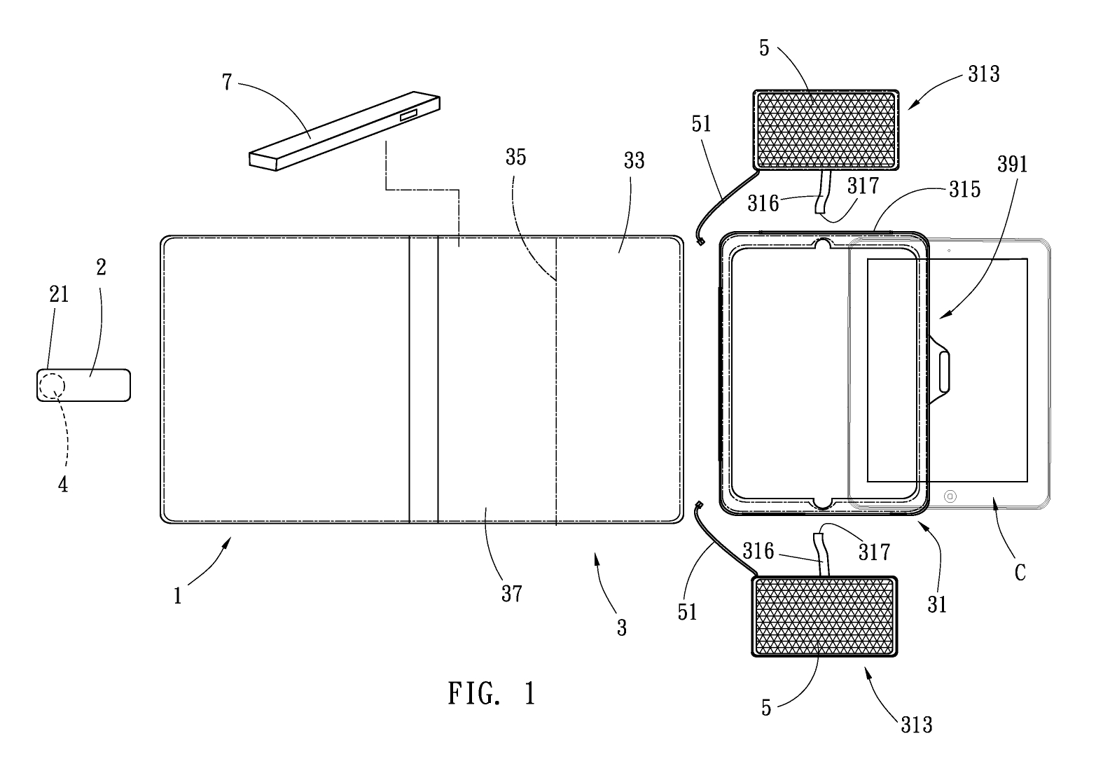

Referring to FIGS. 1-3, a mobile electronic device protective cover in accordance with the present invention is shown a front panel 1 and a rear panel 3. The front panel 1 and the rear panel 3 are hinged together so that they can be turned relative to each other between a received condition where the front panel 1 and the rear panel 3 are overlapped each other and an extended condition where the front panel 1 and the rear panel 3 are kept on one same plane. The rear panel 3 comprises a holder portion 31, a connection portion 33, a folding line 35 and a support portion 37. The holder portion 31 has a back wall 312. The connection portion 33 is bonded to a part, for example, the upper part of the back wall 312 of the holder portion 31. The support portion 37 and the connection portion 33 connected together by means of the folding line 35.

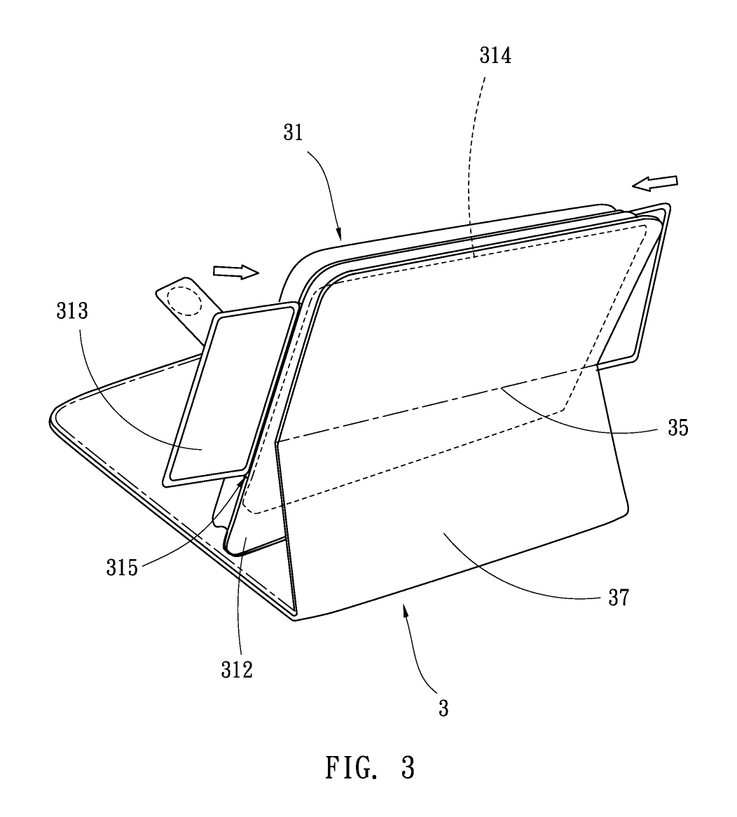

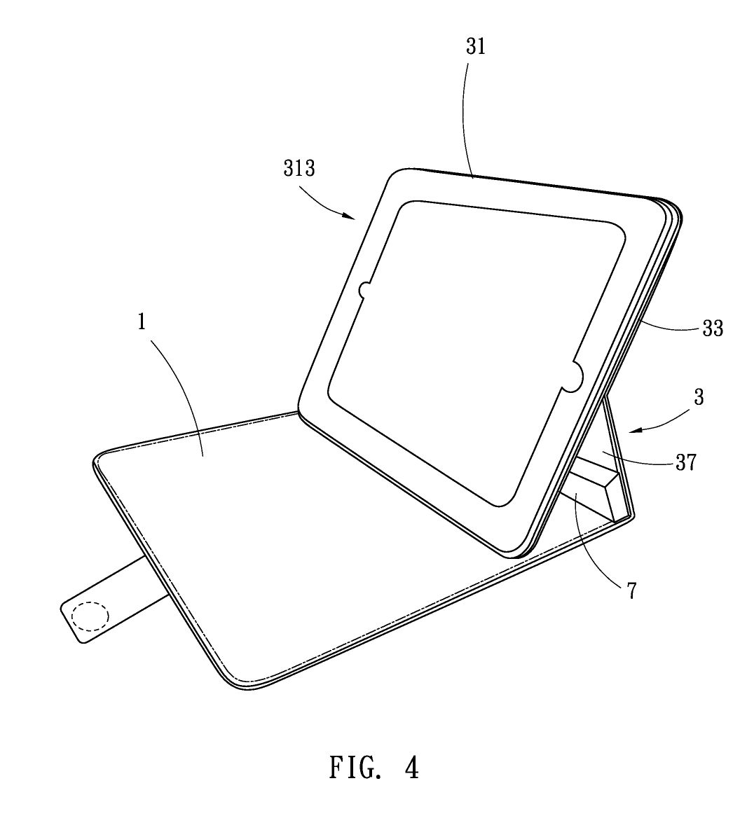

Referring to FIG. 4 and FIG. 3 again, the holder portion 31 of the rear panel 3 is configured to hold a mobile digital data processing device. According to this embodiment, the holder portion 31 of the rear panel 3 is configured to hold a tablet PC. During application, the rear panel 3 is biased relative to the front panel 1 by means of the hinged structure therebetween from a horizontal position to vertical position to let the holder portion 31 stand on the top surface of the horizontally extended front panel 1 in a slightly backwardly inclined standing position. At this time, subject to the arrangement of the connection portion 33 that is bonded to the upper part of the back wall 312 of the holder portion 31 and the effect of the folding line 35 between the connection portion 33 and the support portion 37, the support portion 37 is biased to a forwardly inclined standing position to support the holder portion 31 steadily in the backwardly inclined standing position. Thus, the tablet PC is held in a standing position in the holder portion 31 convenient for reading.

Referring to FIGS. 1-4 again, the holder portion 31 has at least one, for example, two pop-up type flat speaker sleeves 313 attached thereto. Each pop-up type flat speaker sleeve 313 can be received inside the holder portion 31, or extended out of the holder portion 31 for holding a flat speaker.

According to the present preferred embodiment, the holder portion 31 defines therein a passageway 314 extending through opposing left and right sides thereof and an opening 315 at each of the two distal ends of the passageway 314. The aforesaid two pop-up type flat speaker sleeves 313 are accommodated in the passageway 314, and can be respectively pulled out of the openings 315 to the outside of the holder portion 31.

Further, each pop-up type flat speaker sleeve 313 has a strap 316 fixedly fastened to one side thereof. The strap 316 has a free end 317 remote from the pop-up type flat speaker sleeve 313 for fastening to the inside of the passageway 314. Thus, when the pop-up type flat speaker sleeves 313 are pulled out of the holder portion 31, they are kept connected to the holder portion 31 in proximity to the respective openings 315 subject to the constraint of the respective straps 316.

According to the present preferred embodiment, each pop-up type flat speaker sleeve 313 of the rear panel 3 holds therein a flat speaker driver 5 that is equipped with an electrical wire 51. After installation of a tablet PC in the holder portion 31, the electrical wires 51 of the flat speaker drivers 5 in the respective pop-up type flat speaker sleeves 313 are electrically connected to the tablet PC. During application, the holder portion 31 is biased to the backwardly inclined standing position on the horizontally extended front panel 1, and the folding line 35 is guided by the connection portion 33 to bias the support portion 37 to a forwardly inclined standing position to support the holder portion 31 steadily in the backwardly inclined standing position on the horizontally extended front panel 1. Thus, the tablet PC is held in a standing position in the holder portion 31 convenient for reading. Thereafter, the flat speaker drivers 5 with the respective pop-up type flat speaker sleeves 313 are respectively pulled out of the openings 315 and kept at two opposite lateral sides relative to the holder portion 31 (tablet PC) for Hi-Fi audio output.

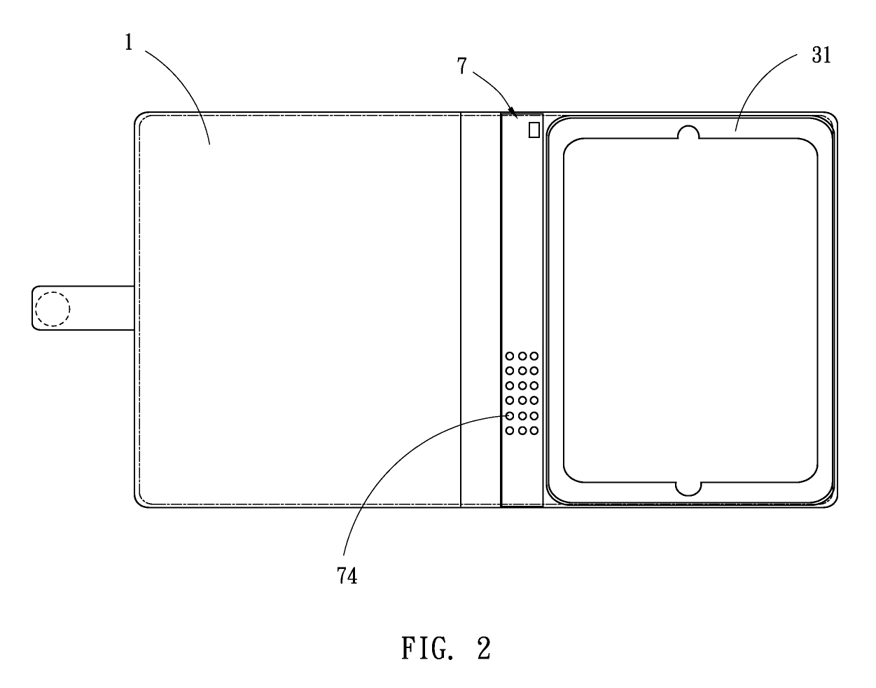

Referring to FIGS. 1 and 2 again, the rear panel 3 further has a box 7 attached to the lower part thereof and abutted against the bottom edge of the holder portion 31. The height of the box 7 fits the holder portion 31 or a tablet PC. The box 7 is adapted for accommodating an acoustic transducer module (not shown), a subwoofer (not shown), a power source or rechargeable battery (not shown) for high-power, high-quality audio performance. This arrangement is not a limitation. In an alternate form of the present invention, the aforesaid pop-up type flat speaker sleeves 313 and flat speaker drivers 5 are eliminated, and the aforesaid subwoofer is directly connected to the acoustic transducer module that is electrically connected to the tablet PC in the holder portion 31. Thus, the tablet PC can use the subwoofer for high-power audio output, providing the best sound quality.

In the aforesaid example, the box 7 has multiple sound penetration holes 74. These sound penetration holes 74 are adapted for assisting the sound performance of the aforesaid subwoofer.

The aforesaid rechargeable battery is electrically connected to the acoustic transducer module to provide the acoustic transducer module and/or the tablet PC with the necessary working voltage. Further, when the cable of the tablet PC is electrically connected to an external power source for charging, the rechargeable battery is also electrically charged at the same time. Electrically arranging the aforesaid acoustic transducer module, subwoofer and rechargeable battery in the box 7 can be easily achieved by a conventional technique. This technique is obvious to any person skilled in the art. No further detailed description or illustration will be necessary.

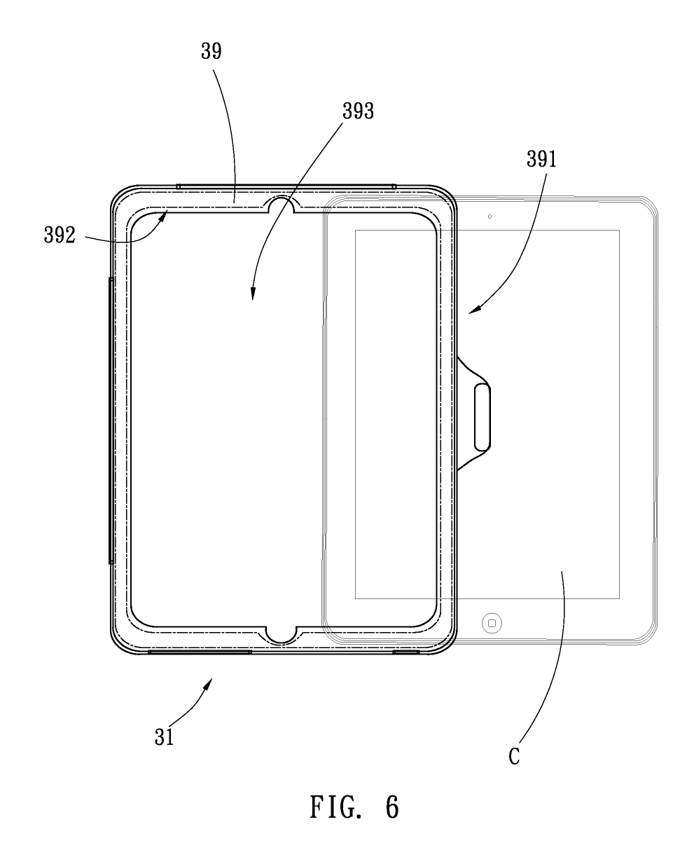

Referring to FIG. 6 and FIG. 3 again, the aforesaid holder portion 31 is provided with a frame 39 located on the front wall thereof opposite to the aforesaid back wall 312. The frame 39 defines an access hole 391, an endless groove 392, and an opening 393. The access hole 391 is formed in one peripheral side of the frame 39 through which a tablet PC C can be inserted into or taken out of the frame 39. The endless groove 392 is defined inside the frame 39. The opening 393 is defined in the middle part of the frame 39 for exposing the display screen of the tablet PC C.

To achieve optimal Hi-Fi field effect output and full-range stereo sound performance, the user can insert the tablet PC C through the access hole 391 into the endless groove 392 in the frame 39, and then electrically connect the electrical wires 51 of the flat speaker drivers 5 to the acoustic transducer module in the box 7 and electrically connect the subwoofer in the box 7 to the acoustic transducer module, and then electrically connect the acoustic transducer module to the tablet PC C by a USB interface or cable. By means of the tablet PC C or the rechargeable battery in the box 7, the acoustic transducer module obtains the necessary working voltage. When the mobile electronic device protective cover is set into the form of a stand to support the tablet PC C in a standing position, the pop-up type flat speaker sleeves 313 and the respective flat speaker drivers 5 are pulled out of the holder portion 31 and held at two opposite lateral sides relative to the holder portion 31. Thus, when the tablet PC C plays an audio or video file, a Hi-Fi sound quality, strong bass and full-range stereo performance is achieved by means of the flat speaker drivers 5.

After an use of the present invention to work as a reading stand or tablet PC stand, the mobile electronic device protective cover can be held in a received condition by turning the front panel 1 and the rear panel 3 toward each other and then securing them in an attached condition by a locking device, which comprises an extension strip 2 affixed to one end of the front panel 1 remote from the rear panel 3, a first magnetic member 4 fixedly located on the free end 21 of the extension strip 2, and a second magnetic member 6 fixedly located on the rear panel 3 and adapted for securing the first magnetic member 4 by magnetic attraction.

In conclusion, the present invention provides a mobile electronic device protective cover that can be set into the form of a stand to hold a tablet PC in a standing position convenient for reading. The mobile electronic device protective cover further comprises two pop-up type flat speaker sleeves 313 adapted for holding two flat speaker drivers 5 at two opposite lateral sides relative to the loaded tablet PC. The pop-up type flat speaker sleeves 313 are receivable in the mobile electronic device protective cover without increasing the thickness or dimension, facilitating carrying. Further, the mobile electronic device protective cover can be equipped with an acoustic transducer module and a subwoofer for high-power, high-quality audio performance, bringing to the user a stunning audio and visual extravaganza.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A mobile electronic device protective cover, comprising a front panel and a rear panel hinged together, said rear panel comprising a holder portion adapted for holding a mobile electronic device, said holder portion defining a back wall, a connection portion bonded to a part of said back wall of said holder portion, a support portion adapted for supporting said holder portion on said front panel in a standing position, and a folding line connected between said connection portion and said support portion.

2. The mobile electronic device protective cover as claimed in claim 1, wherein said holder portion is configured to hold a tablet computer.

3. The mobile electronic device protective cover as claimed in claim 1, wherein said rear panel further comprises at least one pop-up type flat speaker sleeve fastened to said holder portion and movable relative to said holder portion between a received position kept inside said holder portion and an extended position disposed outside said holder portion for holding one respective speaker driver.

4. The mobile electronic device protective cover as claimed in claim 3, wherein said holder portion defines therein a passageway extending through opposing left and right sides thereof and an opening at each of two distal ends of said passageway; said at least one pop-up type flat speaker sleeve is accommodated in said passageway, each having a strap fixedly fastened to one side thereof, said strap having a free end inserted through one opening at one end of said passageway and fixedly fastened to the inside of said passageway.

5. The mobile electronic device protective cover as claimed in claim 1, wherein said rear panel further comprises a box accommodating therein an acoustic transducer module, a subwoofer and a rechargeable power source.

6. The mobile electronic device protective cover as claimed in claim 5, wherein said box comprises a plurality of sound penetration holes corresponding to said subwoofer.

7. The mobile electronic device protective cover as claimed in claim 5, wherein said subwoofer is electrically connected to said acoustic transducer module; said acoustic transducer module is electrically connectable to a tablet PC held in said holder portion for converting outputted audio signals of said tablet PC into sound for output by said subwoofer.

8. The mobile electronic device protective cover as claimed in either of claims 3, wherein each said pop-up type flat speaker sleeve holds therein a respective speaker driver, said speaker driver comprising an electrical wire electrically connectable to an audio output port of a tablet computer being held in said holder portion.

9. The mobile electronic device protective cover as claimed in claim 8, wherein said holder portion comprises a frame located on a front wall thereof opposite to said back wall, said frame defining an access hole through which a tablet computer is insertable into said frame, an endless groove adapted for holding an inserted tablet computer in said frame, and an opening for exposing a display screen of the inserted tablet computer.

10. The mobile electronic device protective cover as claimed in either of claims 9, further comprising a locking device adapted for locking said front panel and said rear panel in a received position, said locking device comprising an extension strip having one end thereof affixed to one end of said front panel remote from said rear panel, a first magnetic member fixedly located on an opposite end of said extension strip, and a second magnetic member fixedly located on said rear panel and adapted for securing said first magnetic member by magnetic attraction.
